(19) United States
(12) Patent Application Publication
(10) Pub. No.: US 2014/0035935 A1
(43) Pub. Date: Feb. 6, 2014

(54) PASSIVES VIA BAR

(71) Applicants: Ravindra V. Shenoy, Dublin, CA (US); Kwan-Yu Lai, San Jose, CA (US); Jon Bradley Lasiter, Stockton, CA (US); Jonghae Kim, San Diego, CA (US); Mario Francisco Velez, San Diego, CA (US); Chi Shun Lo, San Diego, CA (US); Donald William Kidwell, Los Gatos, CA (US); Philip Jason Stephanou, Mountain View, CA (US); Justin Phelps Black, Santa Clara, CA (US); Evgeni Petrovich Gousev, Saratoga, CA (US)

(72) Inventors: Ravindra V. Shenoy, Dublin, CA (US); Kwan-Yu Lai, San Jose, CA (US); Jon Bradley Lasiter, Stockton, CA (US); Jonghae Kim, San Diego, CA (US); Mario Francisco Velez, San Diego, CA (US); Chi Shun Lo, San Diego, CA (US); Donald William Kidwell, Los Gatos, CA (US); Philip Jason Stephanou, Mountain View, CA (US); Justin Phelps Black, Santa Clara, CA (US); Evgeni Petrovich Gousev, Saratoga, CA (US)

(73) Assignee: QUALCOMM MEMS TECHNOLOGIES, INC., San Diego, CA (US)

(21) Appl. No.: 13/566,925

(22) Filed: Aug. 3, 2012

(51) Int. Cl. H05K 7/00; H01F 41/00; G06T 1/00; H01L 21/56; H05K 1/00; H05K 1/09; H01R 43/20; H01L 23/29

(52) U.S. Cl. 345/501; 29/825; 29/602.1; 216/18; 257/774; 438/113; 174/258; 361/748; 361/782; 174/257; 361/746; 257/E23.118; 257/E21.504

(57) ABSTRACT

This disclosure provides systems, methods and apparatus for glass via bars that can be used in compact three-dimensional packages, including embedded wafer level packages. The glass via bars can provide high density electrical interconnections in a package. In some implementations, the glass via bars can include integrated passive components. Methods of fabricating glass via bars are provided. In some implementations, the methods can include patterning and etching photo-patternable glass substrates. Packaging methods employing glass via bars are also provided.

### TECHNICAL FIELD

This disclosure relates generally to packaging of devices and more particularly to glass via bars for interconnecting multiple layers, substrates or components of a package.

### DESCRIPTION OF THE RELATED TECHNOLOGY

Microelectronic devices can include multiple components including and electromechanical systems (EMS) dies. For example, EMS dies can be electrically connected to driver integrated circuit (IC) dies in an electronic device. Electromechanical systems include devices having electrical and mechanical elements, actuators, transducers, sensors, optical components (including mirrors) and electronics. Electromechanical systems can be manufactured at a variety of scales including, but not limited to, microscales and nanoscales. Microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers.

Packaging in a system can protect the functional units of the system from the environment, provide mechanical support for the system components, and provide an interface for electrical interconnections. Three-dimensional (3-D) packaging having multiple stacked dies can reduce package sizes in microelectronic systems.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus including a glass bar having one or more through-glass vias. Example thicknesses of the glass bar can between about 300 and 700 microns and example lengths and widths of the glass bar can be between about 1 and 15 millimeters. Example through-glass via densities can range from 6 vias per millimeter square to 200 vias per millimeter square. Example via diameters can be between about 30 microns and 50 microns. Examples of glass bar materials include photo-patternable glass. Examples of through-glass via materials include plated copper.

In some implementations, the glass bar can include one or more passive devices. Examples of passive devices include inductors, capacitors and resistors. In some implementations, a passive device can be connected to one or more through-glass vias. In some implementations, the glass bar can include two or more through-glass vias connected to form an inductor. In some implementations, the glass bar can include one or more configurable passive devices. For example, in some implementations, a passive device can be configured during an embedded wafer-level process.

Another innovative aspect of the subject matter described in this disclosure can be implemented in a package including a glass bar that includes one or more through-glass vias and a mold embedding the glass bar. In some implementations, the package can further include a semiconductor die embedded in the mold and in electrical communication with the one or more through-glass vias. For example, a package can include a single semiconductor die and a plurality of glass bars embedded in the mold. In another example, a package can include a plurality of semiconductor dies and associated glass bars embedded in the mold. In some implementations, the glass bar can include one or more passive devices.

Another innovative aspect of the subject matter described in this disclosure can be implemented in a method including forming a plurality of passive components on a glass substrate, forming a plurality of through-glass via holes in the glass substrate, metallizing the through-glass via holes, and singulating the glass substrate to form a plurality of glass via bars each having a thickness between about 300 and 700 microns and a length between about 1 and 15 millimeters.

In some implementations, the glass substrate is a photo-patternable glass substrate and forming the plurality of through-glass via holes includes patterning and etching the photo-patternable glass substrate. In some implementations, forming the plurality of through-glass via holes includes laser ablation of the glass substrate. In some implementations, metallizing the through-glass via holes includes electroplating.

The method can further include connecting one or more of the plurality of passive devices to at least one of the plurality of metallized through-glass via holes. In some implementations, the method further includes connecting two or more of the plurality of metallized through-glass via holes to form an inductor.

Another innovative aspect of the subject matter described in this disclosure can be implemented in a method including placing a plurality of semiconductor dies and a plurality of glass via bars on a carrier substrate, embedding the plurality of semiconductor dies and the plurality of glass via bars in a mold compound to form a mold structure, forming one or more redistribution layers on the mold structure, forming inter-level interconnects, and singulating the mold structure to form a plurality of molded dies each including at least one semiconductor, at least one glass via bar, and a plurality of inter-level interconnects. In some implementations, the plurality of glass via bars can include integrated passive components.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1A-1C show examples of isometric schematic illustrations of glass via bars.

FIG. 2 shows an example of an isometric schematic illustration of a portion of a glass via bar including passive components.

FIG. 3 shows an example of a flow diagram illustrating a batch manufacturing process for glass via bars.

FIG. 4 shows an example of a flow diagram illustrating a manufacturing process for a glass via bar using photo-patternable glass.

FIGS. 5A-5G show examples of cross-sectional schematic illustrations of various stages in a method of a making a glass via bar.

FIG. 6A shows an example of a schematic illustration of a top surface of a configurable glass via bar.

FIG. 6B shows an example of a schematic illustration of the top surface of the glass via bar of FIG. 6A after configuration.

FIGS. 7A-7C show examples of cross-sectional schematic illustrations of embedded wafer level packaging (eWLP) packages including glass via bars.

FIG. 8 shows an example of a flow diagram illustrating a packaging process employing a glass via bar.

FIGS. 9A-9H show examples of cross-sectional schematic illustrations of various stages in a method of packaging employing a glass via bar.

FIGS. 10A-10C show examples of various views of a molded die including an embedded semiconductor die and glass via bars.

FIG. 11 shows an example of a schematic cross-sectional illustration of a package-on-package (PoP) that includes glass via bars.

FIG. 12 shows an example of a flow diagram illustrating a PoP packaging process employing a glass via bar.

FIGS. 13A and 13B show examples of system block diagrams illustrating a display device that includes a packaged semiconductor chip in electrical connection with a glass via bar.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. Thus, the teachings are not intended to be limited to the implementations depicted solely in the Figures, but instead have wide applicability as will be readily apparent to one having ordinary skill in the art.

Some implementations described herein relate to glass via bars that include through-glass vias. The glass via bars can be used, for example, to provide inter-level connections in stacked three-dimensional (3-D) packages. In some implementations, the glass via bars can be part of an embedded wafer level package. In some implementations, the glass via bars can include high density arrays of through-glass vias. In some implementations, the glass via bars can include one or more passive components on a surface of and/or embedded within the glass via bars. In some implementations, a glass via bar can be configurable, including banks of unconnected through-glass vias and/or passive components that can be configured for particular applications, for example, during packaging.

Some implementations described herein relate to packages including glass via bars. The packages can include one or more semiconductor dies and one or more glass via bars embedded within a mold structure. The glass via bars can have one or more passive components on or within the glass via bars. The packages can further include inter-level interconnects such as solder balls. In some implementations, the packages can further include one or more components such as a surface mount technology (SMT) components, filters, and MEMS dies.

Some implementations described herein relate to methods of fabricating glass via bars. Methods of fabricating glass via bars can include forming and filling through-glass via holes of a large-area glass substrate and singulating the substrate to form multiple glass via bars. In some implementations, passive components can be formed on the glass substrate prior to singulation. In some implementations, forming through-glass via holes can include patterning and etching photo-patternable glass. Some implementations described herein relate to methods of fabricating packages including glass via bars. Methods of fabricating packages including glass via bars can include forming a mold structure embedding one or more semiconductor dies and one or more glass via bars.

Particular implementations of the subject matter described in this disclosure can be implemented to realize one or more of the following potential advantages. In some implementations, the glass via bars can provide the ability to scale the via pitch from 500 microns to 50 microns and the via diameter from 200 microns to 30 microns. Advantages of scaling the pitch and diameter include fabricating smaller packages and increasing capacity and flexibility in package design.

In some implementations, passive components can be co-fabricated with and incorporated into the glass via bar. Advantages of incorporating passive components into the glass via bar include the ability to place the passive components closer to semiconductor dies in a package, reducing the electrical path length, increasing performance, reducing the number of components, simplifying assembly, and reducing cost. Further, for certain applications such as RF applications, incorporating passive components on or in a glass bar can reduce loss tangent in these passive components, which can in turn reduce power consumption, increase the quality factor, and reduce interference with other devices. In some implementations, incorporating a solenoid-type inductor into a glass bar can allow confinement of electromagnetic field lines horizontally with the low loss glass bar. Advantages of confining electromagnetic field lines horizontally include reducing interference with devices packaged above or below the glass bar.

In some implementations, the glass via bars can include configurable passive components. Advantages of providing configurable passive components include the ability to tailor the glass via bars during packaging for particular applications, providing a standard template for a variety of applications, simplified manufacturing, reduced design time, faster development time, and lower cost. In some implementations, the glass via bars can be tested prior to incorporation into a package. The ability to test vias and passive components can provide high yields. In some implementations, the glass via bars can facilitate fabrication of stacked die packages.

Packaging of devices, including EMS devices and integrated circuit devices, can protect the functional units of the devices from the environment, provide mechanical support for the devices, and provide a high-density interface for electrical interconnections between devices and substrates.

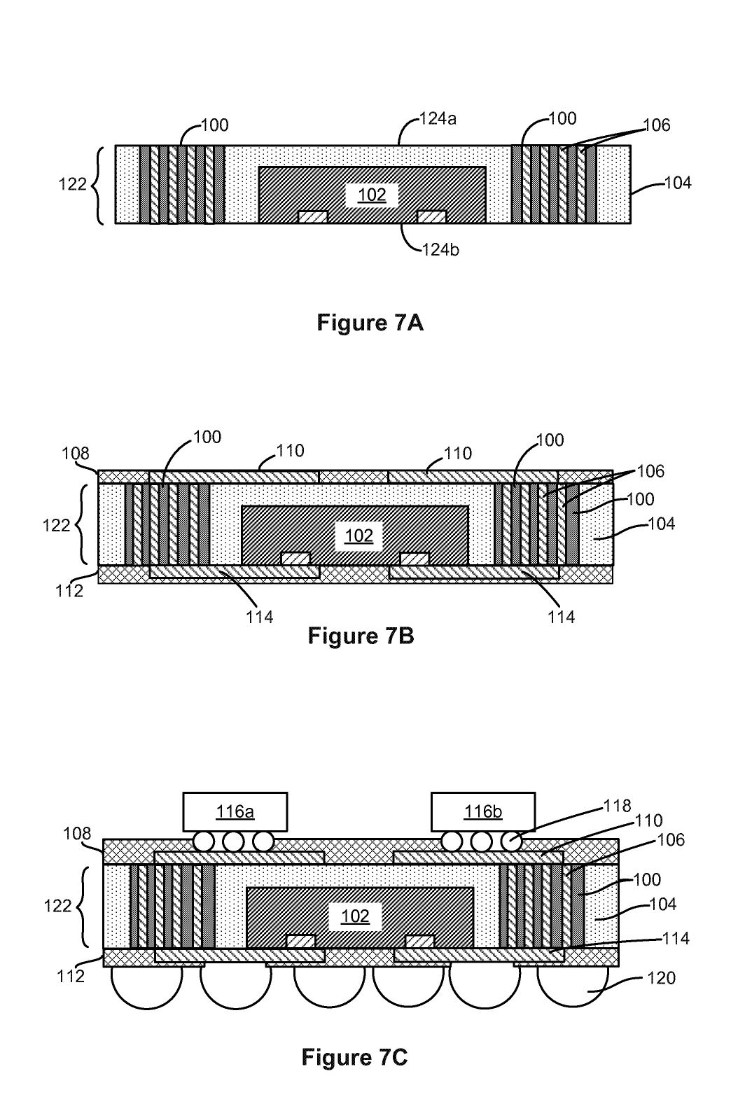

Implementations described herein relate to glass via bars that include through-glass vias. The glass via bars can be used, for example, to provide inter-level connections in stacked three-dimensional (3-D) packages. In some implementations, the glass via bars can be part of an embedded wafer level package. Embedded wafer level packaging (eWLP), also referred to as extended wafer level packaging, leverages wafer level processing to package singulated dies, such as semiconductor dies. The dies are placed on a carrier substrate, and a curable compound is used to fill gaps between the dies and the edges around the dies. The cured compound forms a mold frame around the dies. The dies and molding form an artificial wafer, also referred to as a reconfigured wafer, which can then undergo wafer level processing including addition of a redistribution layer and solder balls, followed by package singulation. eWLP can also be referred to as embedded or extended wafer level ball grid array (eWLB), fan out wafer level chip scale packaging (fan out WLCSP), fan out wafer level packaging (fan out WLP) and advanced wafer level packaging (aWLP). eWLP packages including glass via bars are described further below with respect to FIGS. 7A-7C.

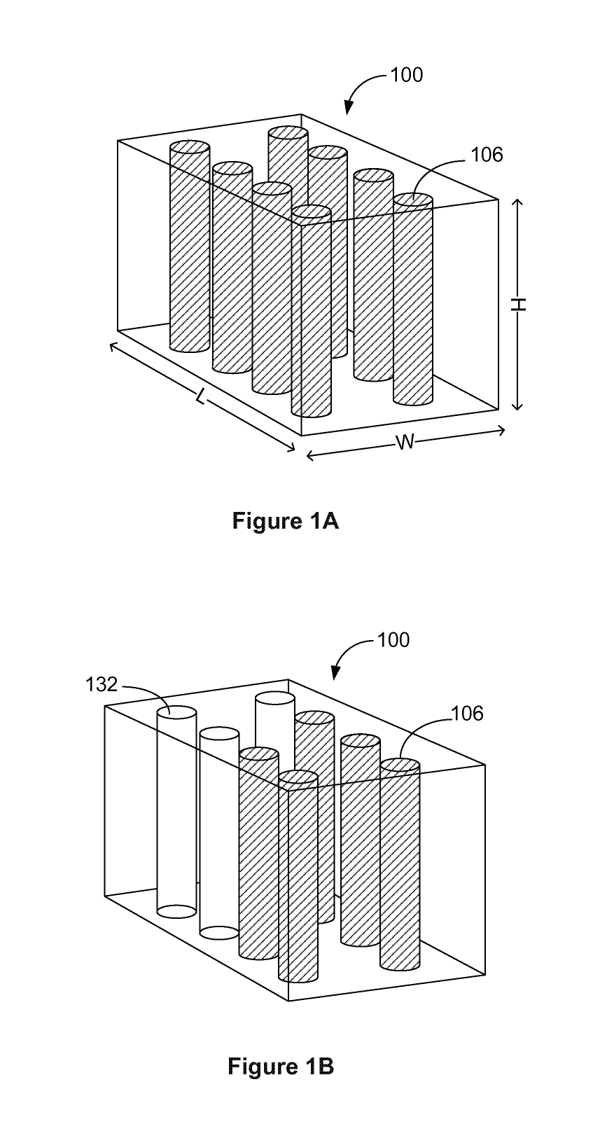

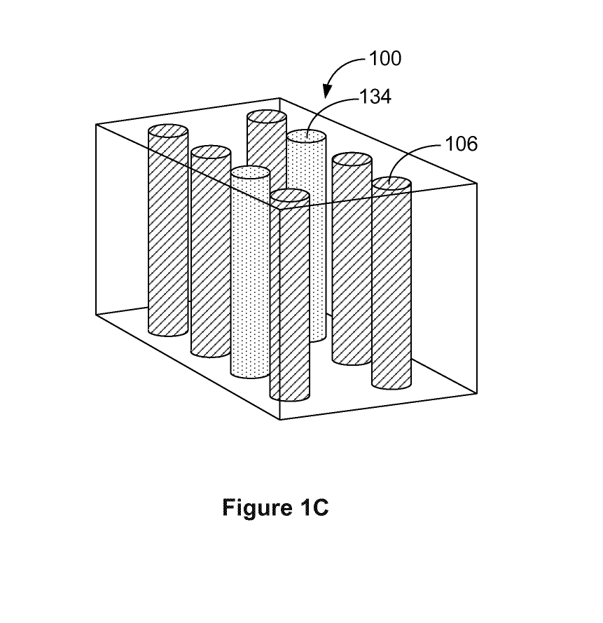

FIGS. 1A-1C show examples of isometric schematic illustrations of glass via bars. FIG. 1A shows an example of a glass via bar 100 including through-glass vias 106. The glass via bar 100 has a length L, a width W and a height H. (It should be noted that the geometry is not shown to scale with the height expanded for the purposes of illustration.) Example dimensions of the glass via bar 100 include a length L between about 1 mm and 6 mm, a width W between about 1 mm and 6 mm, and a height H between about 300 microns and 700 microns. In implementations in which the glass via bar 100 is to be packaged in a mold structure as described below with respect to FIGS. 7A-7C, the height H can be the equal to the thickness of the mold structure. In some implementations, the length and width of the glass via bar can be larger, for example, up to about 15 mm. While the glass via bar 100 in the example of FIG. 1A and the remaining Figures is a rectangular cuboid, the glass via bar 100 may have any shape. For example, the glass via bar 100 may have a 3-D L-shape, a cylindrical shape, or other shape appropriate for a particular package layout, with dimensions on the order of about 1 mm to 15 mm. Moreover, although it is depicted as transparent in the associated Figures, the glass via bar 100 may be transparent or non-transparent. The glass via bar can be a borosilicate glass, a soda lime glass, quartz, Pyrex, or other suitable glass material. In some implementations, the glass substrate is a borosilicate glass substrate that can be ablated by laser radiation. In some implementations, the glass substrate is a photo-patternable glass substrate.

The through-glass vias 106 extend through the glass via bar 100, providing conductive pathways between opposing faces. Example diameters of the glass vias 106 can range from about 30 microns and 100 microns. The through-glass vias 100 can also have any appropriate shape. For example, in certain implementations, via openings for through-glass vias 100 can be circular, semi-circular, oval, rectangular, polygonal, rectangular with rounded edges, polygonal sharp edges, or otherwise shaped. Also according to various implementations, the through-glass vias 100 can have linear or curved sidewall contours. The glass via bar 100 can include any number of through-glass vias placed or arrayed in any regular or irregular arrangement. For example, the glass via bar 100 may have between about 1 and 24 through-glass vias 106. Example pitches (center-to-center distances) of the through-glass vias 106 in the glass via bar can range from about 40 microns to about 200 microns.

In some implementations, the glass via bar 100 may include unfilled through-glass via holes. FIG. 1B shows an example of a glass via bar 100 including through-glass vias 106 and unfilled through-glass via holes 132, which can be formed into through-glass vias by the addition of conductive material. In some implementations, the through-glass via bar may be provided with an arrangement of through-glass via 106 and unfilled through-glass via holes 132 for a particular packaging layout. The unfilled through-glass via holes 132 can facilitate large scale production of the glass via bars 100 without wasting conductive material not used for the particular layout. In some implementations, the glass via bar 100 may include through-glass via holes filled with a non-conductive material. FIG. 1C shows an example of a glass via bar 100 including through-glass vias 106 and filled non-conductive via holes 134. In some implementations, the filled non-conductive via holes 134 can be filled with a thermally conductive filler material. The thermally conductive filler material may serve as a thermally conductive path to transfer heat from devices on one side of the glass via bar 100 to the other. In some implementations, the filled non-conductive via holes 134 can be filled with a filler material that seals the via holes to prevent transfer of liquids or gases through the via holes. In some implementations, the filled non-conductive via holes 134 can be filled with a filler material that provides mechanical support and/or stress relief to the glass via bar 100. In some implementations (not shown), the glass via bar 100 may include through-glass via holes conformally coated with a conductive material. The interior of the through-glass via holes can be left unfilled or filled with a non-conductive material as described above.

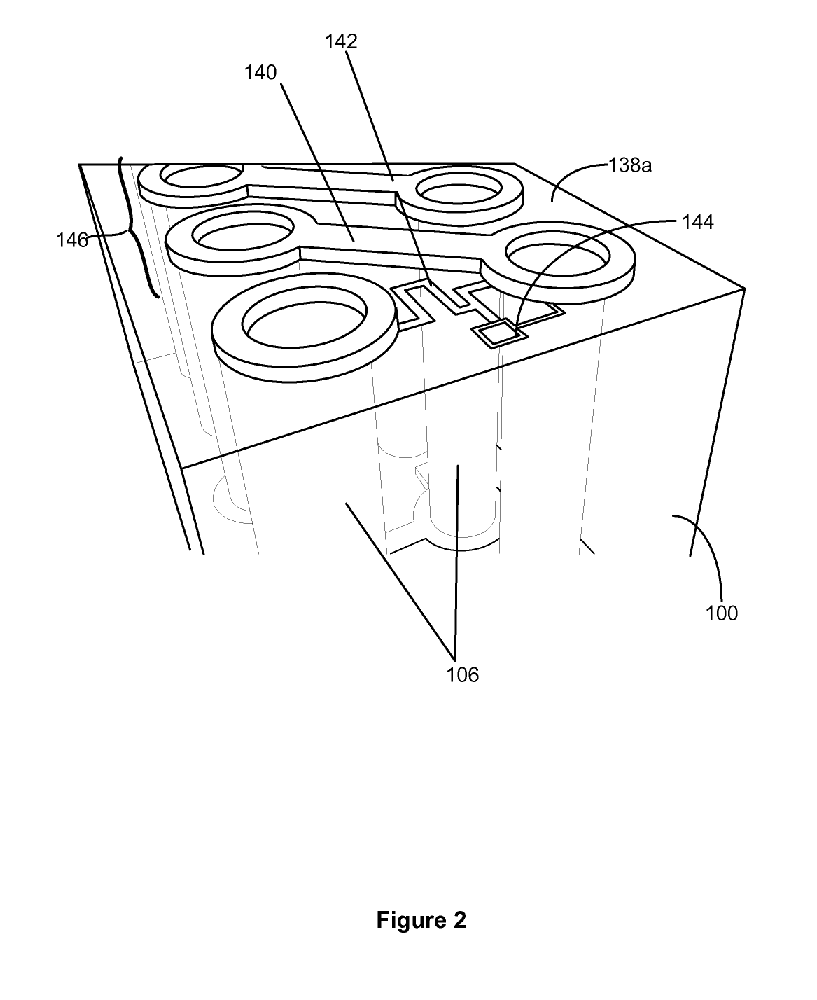

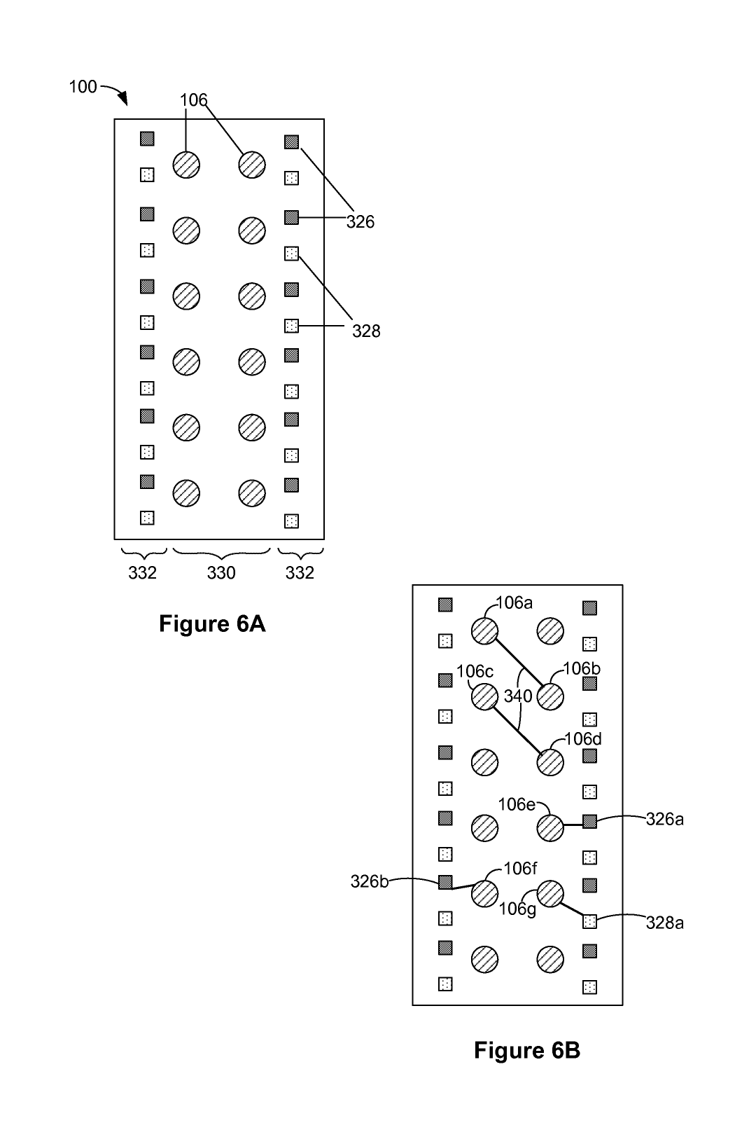

In some implementations, the glass via bar 100 is provided with conductive routing on one or more of its faces. In some implementations, the glass via bar 100 is provided with one or more integrated passive components. An integrated passive component is a passive component provided on one or more of faces or embedded within the glass via bar 100. FIG. 2 shows an example of an isometric schematic illustration of a portion of a glass via bar including passive components. The glass via bar 100 includes a top surface 138a and through-glass vias 106 that extend through the glass via bar 100. Passive components including a capacitor 144 and a resistor 142 can be formed on the top surface 138a. Plated conductive routing 140 also can be formed on the surface 138a. In some implementations, multiple through-glass vias 106 can be connected to form a solenoid-type inductor. In the example of FIG. 2, a portion of a solenoid inductor 146 formed by connecting multiple through-glass vias 106 on the top surface 138a and the bottom surface (not shown) is depicted. As illustrated, to form the solenoid inductor 146, through-glass vias are connected to diagonally adjacent through-glass vias on the top surface 138a of the glass via bar while through-glass vias are connected to laterally adjacent vias on the bottom surface of the glass via bar, and vice versa. In some implementations, a configurable glass via bar can be provided with a plurality of passives formed one or more surfaces unconnected to a plurality of through-glass vias. The configurable glass via bar can be configured during an eWLP process, for example, with all or a subset of surface passive components connected to one or more through-glass vias and/or all or a subset of through-glass vias interconnected to form one or more solenoid-type inductors. Configurable glass via bars are further discussed below with respect to FIGS. 6A and 6B.

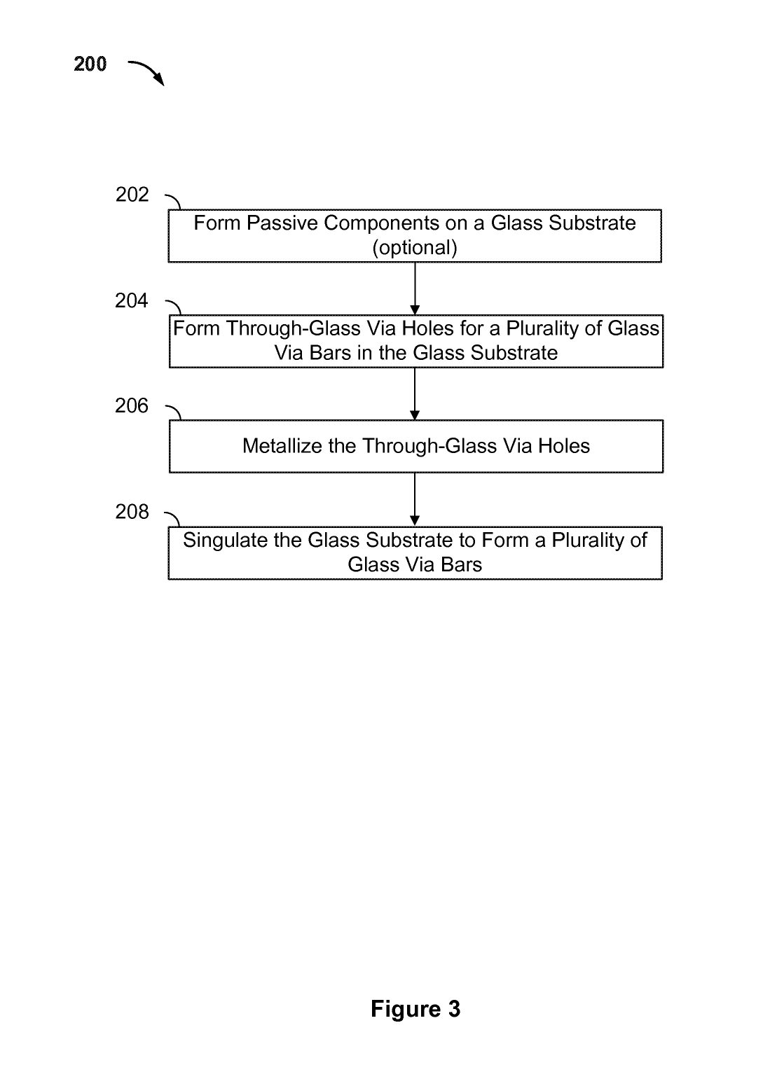

Manufacturing processes for fabricating glass via bars are described below with respect to FIGS. 3-5G. In some implementations, glass via bars can be fabricated in batch level processes. Batch level processes form a plurality of glass via bars simultaneously. FIG. 3 shows an example of a flow diagram illustrating a batch manufacturing process for glass via bars. The process 200 begins at a block 202 with forming passive components for a plurality of glass via bars on one or more surfaces of a glass substrate. The glass substrate can be a panel, sub-panel, wafer, sub-wafer or other appropriate type of substrate. For example, in some implementations, the glass substrate can be a glass plate or panel having an area on the order of four square meters or greater. In some other implementations, the glass substrate can be a round substrate with a diameter of 100 mm, 150 mm or other appropriate diameter. The thickness of the glass substrate can be the same as the height of the glass via bars that are to be fabricated from the glass substrate. Example thicknesses range from about 300 microns to about 700 microns. In some implementations, the thickness of the glass substrate can be greater than that the glass via bars, if for example, the glass substrate can be thinned in subsequent processing.

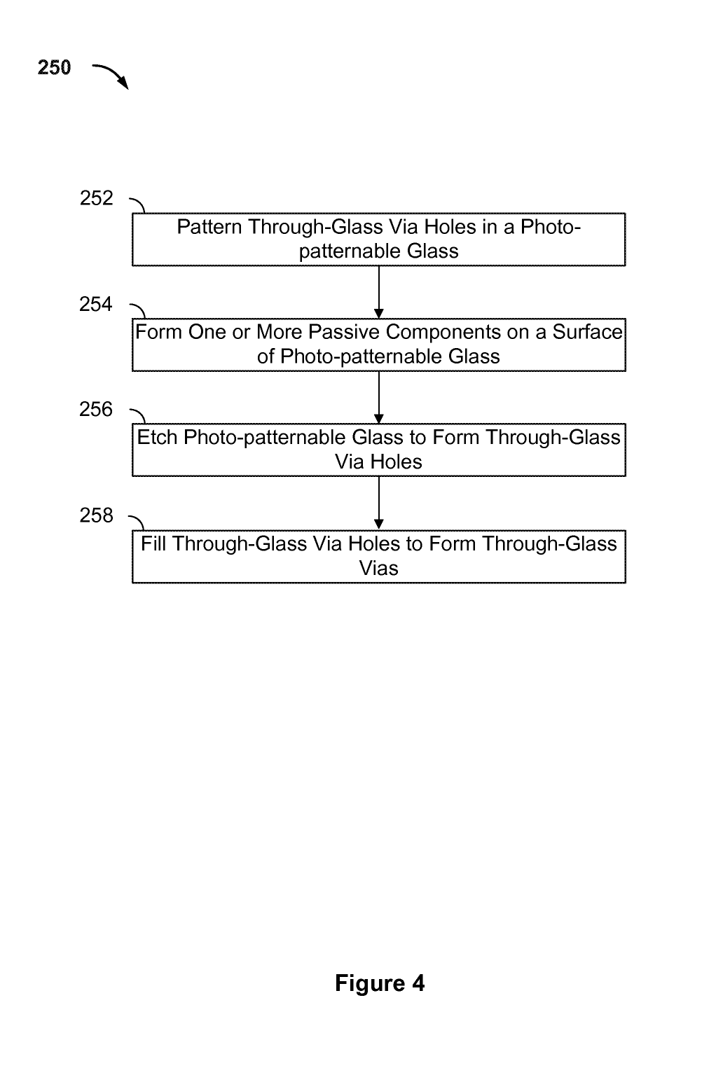

The glass substrate may be or include, for example, a borosilicate glass, a soda lime glass, quartz, Pyrex, or other suitable glass material. In some implementations, the glass substrate is a borosilicate glass substrate that can be ablated by laser radiation. In some implementations, the glass substrate can have a coefficient of thermal expansion (CTE) matched to the CTE of another component of a package, or between the CTEs of two or more components of a package. For example, a glass substrate can have a relatively low CTE of about 3.4 ppm/° C. matched to silicon, a relatively high CTE of about 10 ppm/° C. matched close a printed circuit board or mold compound, or a CTE between these components. In some implementations, the glass substrate is a photo-patternable glass substrate. Photo-patternable glasses are discussed further below with respect to FIG. 4.

Forming passive components on one or more surfaces of the glass substrate can include one or more thin film deposition and etching operations. For example, one or more metal, dielectric and passivation layers can be deposited and patterned to form the passive components. Examples of deposition techniques can include PVD, CVD, atomic layer deposition (ALD), electrolytic plating, and electroless plating. In some implementations, the passive components include one or more capacitors, inductors, and/or resistors. In some implementations, the passive components can include a variable capacitor, a varactor, a filter, a transformer, a coupler, a directional coupler, a power splitter, a transmission line, a waveguide and/or an antenna.

The process 200 continues at block 204 with formation of through-glass via holes for a plurality of glass via bars in the glass substrate. Block 204 can involve a sandblasting process, laser ablation process, or photo-patterning process. The process 200 continues at block 206 with metallization of the through-glass via holes to form through-glass vias. Block 206 can include, for example, a plating process such as electroless or electroplating. In some implementations, the through-glass vias can be filled with a metal. In some other implementations, the interior surfaces of the through-glass via holes can be coated with a metal, with the remaining portions of the through-glass via holes left unfilled or filled with a conductive material, such as a metal, or a non-conductive material, such as a dielectric. Block 206 also can include forming one or more routing lines on one or more surfaces of the glass substrate, for example, to electrically connect multiple through-glass vias.

In some implementations, the through-glass vias can be connected to one or more surface passive components and/or interconnected to each other to form, for example, one or more solenoid-type inductors after block 204. In some implementations, some or all of the through-glass vias formed in block 206 and the surface passive components formed in block 202 can be left unconnected after block 206. In some such implementations, the through-glass vias and the passive components can be connected in subsequent processing, for example, during an eWLP process.

The process 200 continues at block 208 with singulating the glass substrate to form a plurality of glass via bars, each including through-glass vias and, if formed, surface passive components. Dicing can include forming dicing streets along which the glass substrate will be cut and cutting along the dicing streets with a dicing saw or laser. According to various implementations, the lateral dimensions of the glass via bars formed in block 208 can be between about 1 mm and 15 mm, for example between about 1 and 6 mm.

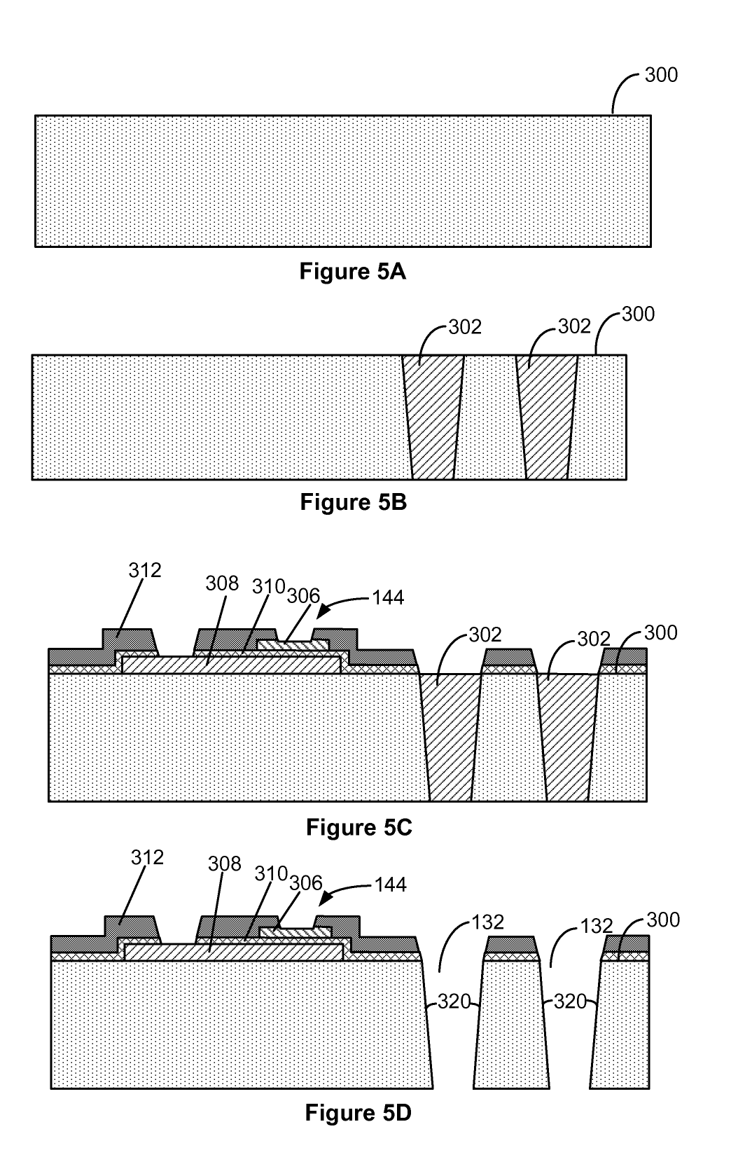

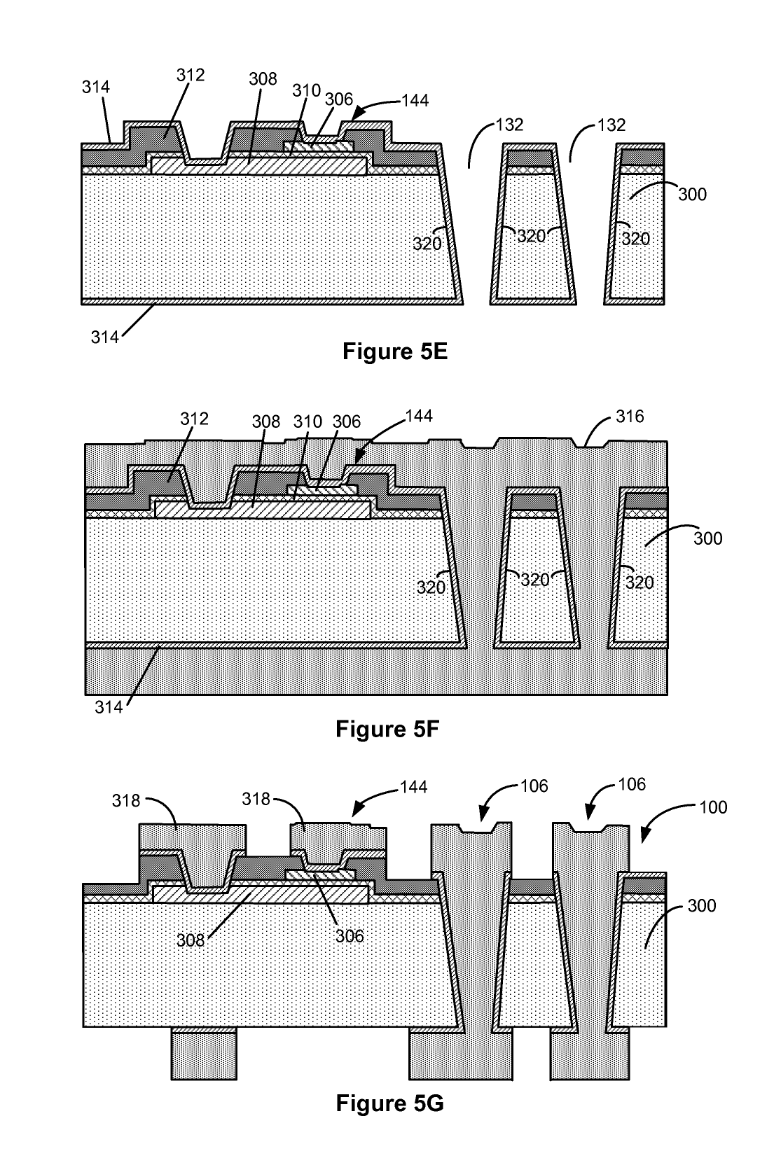

FIG. 4 shows an example of a flow diagram illustrating a manufacturing process for a glass via bar using photo-patternable glass. FIGS. 5A-5G show examples of cross-sectional schematic illustrations of various stages in a method of making a glass via bar. First turning to FIG. 4, the process 250 begins at block 252 with patterning through-glass via holes in a photo-patternable glass. In some implementations, “patterning” can refer to changing the chemical or crystalline structure of the photo-patternable glass to form altered regions and un-altered regions. Photo-patternable glasses can include silicon oxide/lithium oxide (SiO₂/Li₂O)-based glasses doped with one or more noble metals such as silver (Ag) and cerium (Ce). Treating the photo-patternable glass with electromagnetic radiation and heat can result in chemical reactions that render the glass etchable with etchants such as hydrofluoric (HF) acid. Examples of photo-patternable glasses include APEX™ glass photo-definable glass wafers by Life BioScience, Inc. and Forturan™ photo-sensitive glass by Schott Glass Corporation. Patterning the photo-patternable glass can include masking the glass to define the through-glass via holes and exposing the unmasked portions of the glass body to ultraviolet (UV) light and thermal annealing. Examples of mask materials can include quartz-chromium. The UV exposure can change the chemical composition of the unmasked portions such that they have high etch selectivity to certain etchants. For example, in some implementations, a masked glass is exposed to UV light having a wavelength between 280 and 330 nanometers. Exposure to UV light in this range can cause photo-oxidation of Ce³⁺ ions to Ce⁴⁺ ions, freeing electrons. Ag⁺ ions can capture these free electrons, forming Ag atoms. In some implementations, a two-stage post-UV exposure thermal anneal can be performed. In the first stage, Ag atoms can agglomerate to form Ag nanoclusters. In the second stage, crystalline lithium silicate (Li₅SiO₃) forms around the Ag nanoclusters. The masked regions of the glass are chemically unchanged and remain amorphous. Thermal anneal temperatures can range from about 500° C. to about 600° C., with the second stage performed at a higher temperature than the first stage. The crystalline portions of the glass can be etched in subsequent processing, for example in block 256, while leaving the vitreous amorphous portions substantially unetched.

The above-described process is one example of patterning a photo-patternable glass, with other processes possible. In some implementations, for example, the glass may include Al, Cu, boron (B), potassium (K), sodium (Na), zinc (Zn), calcium (Ca), antimonium (Sb), arsenic (As), gold (Au), magnesium (Mg), barium (Ba), lead (Pb), or other additives in addition to or instead of the above-described components. In some implementations, the photo-patternable glass may include various additives to modify melting point, increase chemical resistance, lower thermal expansion, modify elasticity, modify refractive index or other optical properties, or otherwise modify the characteristics of the glass. For example, potassium oxide (K₂O) and/or sodium oxide (Na₂O) may be used to lower the melting point and/or increase chemical resistance of the photo-patternable glass and zinc oxide (ZnO) or calcium oxide (CaO) may be used to improve chemical resistance or reduce thermal expansion. In some implementations, one or more other electron donors may be used in addition to or instead of Ce. In some implementations, the photo-patternable glass may include one or more oxygen donors.

Example UV dosages can range from 0.1 J/cm² to over 50 J/cm². The UV wavelength and dosage can vary according to the composition and size of the photo-patternable glass. The UV-induced chemical reactions can also vary depending on the chemical composition of the photo-patternable glass, as can the subsequent thermal-induced reactions. Moreover, in some implementations, these reactions may be driven by energy sources other than UV radiation and thermal energy, including but not limited to other types of electromagnetic radiation. In general, treating the unmasked areas of the photo-patternable glass with one or more types of energy produces can produce crystalline composition such as polycrystalline ceramic. The conversion to a crystalline ceramic allows the photo-patternable glass to be etched.

FIG. 5A shows an example of a cross-sectional schematic illustration of a photo-patternable glass prior to patterning. Glass substrate 300 is a photo-patternable glass and can be, for example, a SiO₂/Li₂O-based glass as described above, and can have a thickness for example, between about 300 microns and 700 microns. In some implementations in which the glass via bars are formed as part of a batch process as described above with respect to FIG. 3, the depicted portion of the glass substrate 300 can be one repeat unit of a larger glass panel or wafer. FIG. 5B shows an example of a cross-sectional schematic illustration of the photo-patternable glass after patterning, for example, after block 252 in FIG. 4. The glass substrate 300 includes crystalline portions 302, which extend through the thickness of the glass substrate 300 and that will eventually be etched to form through-glass via holes. In the example of FIG. 5B, the crystalline portions 302 have a slightly angled profile. Accordingly to various implementations, the crystalline portions 302, and thus the through-glass via holes, can have substantially straight sidewalls with an angle ranging from about 80° to about 90° from the top surface of the photo-patternable glass.

Returning to FIG. 4, the process 250 continues at a block 254 with forming one or more passive components on a surface of the photo-patternable glass. As described above with respect to FIG. 3, forming one or more passive components can include thin film deposition and patterning operations. FIG. 5C shows an example of a cross-sectional schematic illustration of a photo-patternable glass including a capacitor formed on a surface of the photo-patternable glass. The capacitor 144 includes metal layers 306 and 308 and dielectric layer 310. The dielectric layer 310 and a passivation layer 312 cover the amorphous portions of the glass substrate 300. Contact points to each of the metal layers 306 and 308 are patterned. Examples of metal layers can include but are not limited to Al, Mo, Cu, and alloys and combinations thereof, such as aluminum niodium (AlNd) and aluminum copper (AlCu). Examples of dielectric materials can include but are not limited to SiO₂, silicon oxynitrides, zirconium oxide (ZrO), and laminated dielectrics.

Returning to FIG. 4, the process 250 continues at a block 256 with etching the photo-patternable glass to form through-glass via holes. Any etch chemistry having a substantially higher etch selectivity for the crystalline portions 302 of the glass substrate 300 than the amorphous portions of the glass substrate 300 can be used, including wet and dry etching. In one example, 10% HF solution can be employed for wet etching. In another example a fluorine-based dry etch can be employed, using a chemistry such as XeF₂, tetrafluoromethane (CF₄) or sulfur hexafluoride (SF₆). The etchant exposure time is long enough such that the photo-patternable glass is etched through its thickness, forming the through-glass via holes. In some implementations, the etch is followed by a post-etch bake.

FIG. 5D shows an example of a cross-sectional schematic illustration of a glass substrate after etch of through-glass via holes. The amorphous portions of the glass substrate 300 remain, with the crystalline portions etched away to form through-glass via holes 132. In alternate implementations, the through-glass via holes 132 can be formed by laser ablation of a laser-ablatable glass substrate. The through-glass via holes 132 include interior surfaces 320, also referred to as sidewall surfaces.

The process 250 continues at block 258 with filling the through-glass via holes 132. In some implementations, block 258 can include forming a seed layer on an interior surface of the through-glass via holes, followed by plating to fill the through-glass via holes. A seed layer may be deposited by a process such as PVD, CVD, ALD, or an electroless plating process. In some implementations, the seed layer may include titanium nitride (TiN), ruthenium-titanium nitride (Ru—TiN), platinum (Pt), palladium (Pd), Au, Ag, Cu, nickel (Ni), Mo, or tungsten (W). In some implementations, the through-glass via holes are filled by electroplating. Examples of plated metals can include Cu, Ni, Au, and Pd, and alloys and combinations thereof. In some implementations, block 250 can further include patterning one or more of the top and bottom surfaces of the glass to electrically isolate the through-glass vias and/or passive components, form routing and contacts to the through-glass vias and/or passive components, interconnect multiple through-glass vias to form solenoid-type inductors, and the like.

FIG. 5E shows an example of a cross-sectional schematic illustration of a glass substrate after through-glass via hole sidewall and surface metallization. The exposed surfaces of the structure in FIG. 5E, including the interior surfaces 320 of the through-glass via holes 132, the exposed surfaces of the metal layers 306 and 308, and the passivation layer 312 are conformally coated with a seed layer 314. FIG. 5F shows an example of a cross-sectional schematic illustration of a glass substrate after plating to fill the through-glass via holes. A plated metal 316 fills the through-glass via holes 132 shown in FIG. 5E, and covers the conformal seed layer 314. As described above, the plated metal 316 can be patterned in a subsequent operation, as shown in FIG. 5G.

FIG. 5G shows an example of a cross-sectional schematic illustration of a glass via bar including through-glass vias and a passive component. The glass via bar 100 includes through-glass vias 106 formed in a glass substrate 300 and a capacitor 144 formed on a surface of the glass substrate 300. The glass via bar 100 also includes plated contacts 318 to metal layers 306 and 308 of the capacitor 144.

In some implementations, a configurable glass via bar can be provided. A configurable glass via bar can have one or more “banks” of components, i.e., one or more groups of components available for use. For example, a configurable glass via bar can have a bank of through-glass vias or a bank of passive components available for connection. In some implementations, a configurable glass via bar can have a bank of through-glass vias and a bank of one or more types of passive components available for connection. FIG. 6A shows an example of a schematic illustration of a top surface of a configurable glass via bar. A glass via bar 100 includes a via bank 330 and passive component banks 332. The bottom surface (not shown) may or may not have one or more passive component banks The via bank 330 includes arrayed through-glass vias 106 and the passive component banks 332 include surface passive components 326 and surface passive components 328. Surface passive components 326 and 328 can be different types of passive components formed on a surface of the glass via bar 100; for example, the surface passive components 326 can be resistors and the surface passive components 328 can be capacitors. The via bank 330 can include any number of through-glass vias arranged in an appropriate layout. Each passive bank 332 can contain any number of different types of passive components in any appropriate layout, with any number of components of any type. The glass via bar 100 can include one or more via banks 330 and one or more passive component banks 332. In some implementations, the glass via bar 100 can include a via bank 330 with no banks of surface passive components. The glass via bar 100 in the example of FIG. 6A is configurable, with both the through-glass vias 106 and the surface passive components 326 and 328 available for configuration. In some implementations, configurable, generic glass via bars can be provided for further configuration in downstream processing, such as during eWLP.

FIG. 6B shows an example of a schematic illustration of the top surface of the glass via bar of FIG. 6A after configuration. Through-glass vias 106a-106d are connected by routing lines 340 and similar routing lines on the bottom surface (not shown) to form a solenoid-type inductor. Through-glass via 106e is connected to surface passive component 326a, through-glass via 106f is connected to surface passive component 326b and through-glass via 106g is connected to surface passive component 328a. Once so configured, the surface passive components 326a and 328a may no longer be configurable. The configuration shown in FIG. 6B provides one example of a possible configuration, with any arrangement of connections desired for a particular package also possible. In some implementations, a configurable glass via bar can be configured for a desired application during an eWLP process or other packaging process. Once configured for a particular application, a glass via bar may no longer be configurable.

As indicated above, in some implementations, the glass via bars described herein can be part of a can be part of eWLP packages. An eWLP package includes one or more components embedded in a singulated mold compound. FIGS. 7A-7C show examples of schematic cross-sectional illustrations of eWLP packages that include glass via bars. First turning to FIG. 7A, a mold structure 122 having a top surface 124a and a bottom surface 124b is depicted. The mold structure 122 includes a mold compound 104 as well as components embedded within the mold compound 104; in the example of FIG. 7A, these components include a semiconductor die 102 and glass via bars 100. Each of the glass via bars 100 includes through-glass vias 106 that extend through the thickness of the glass via bar 100 and provide electrical connections from the top surface 124a of the mold structure 122 to the bottom surface 124b. While the mold structure 122 in the example of FIG. 7A includes a single die, an arbitrary number of dies can be included according to various implementations.

In some implementations, an eWLP package includes one or more redistribution layers (RDLs) on one or both sides of a mold structure. FIG. 7B shows an example of a schematic cross-sectional illustration of an eWLP package including redistribution layers. The eWLP package includes a mold structure 122 as described above with respect to FIG. 7A and RDL layers 108 and 112. The RDL layers 108 and 122 can include electrically conductive routing lines and contacts embedded in a dielectric material for carrying electrical signals. In the example of FIG. 7B, the RDL layer 112 includes routing lines 114, which electrically connect the semiconductor die 102 to the through-glass vias 106 of the glass via bars 100, and connect the semiconductor die 102 and the through-glass vias 106 to RDL pads (not shown) for further connection to inter-level interconnects. The RDL layer 108 includes RDL pads 110, which are electrically connected to the through-glass vias 106 of the glass via bars 100 and provide a contact point for one or more overlying dies or other components. In some implementations, electrically conductive routing lines and pads can be embedded within the mold structure 112 or disposed on one or both of the top and bottom surfaces 124a and 124b of the mold structure. In some implementations, a RDL layer can be a multi-layer redistribution network including alternating layers of metallization and dielectric material.

An eWLP package can further include inter-level interconnects configured to connect the mold structure to one or more underlying or overlying substrates, dies, devices or other components. FIG. 7C shows an example of a schematic cross-sectional illustration of an eWLP package including inter-level interconnects. The eWLP package includes a mold structure 122 and RDL layers 108 and 112 as described above with respect to FIGS. 7A and 7B, and inter-level interconnects 118 and 120. The inter-level interconnects can include appropriate electrical interconnection such as under bump metallization (UBM) or solder balls. In the example of FIG. 7C, the inter-level interconnects 118 electrically connect top-side components 116a and 116b. In some implementations, the inter-level interconnects can connect to another layer or substrate, including another mold structure. It should be noted that the size, pitch, and placement of inter-level interconnects 118 and 120 and other ball array or other interconnects described in this disclosure can be varied as appropriate.

The top-side components 116a and 116b can each be any appropriate component including any WLCSP die or surface mount technology (SMT) component. In one example, embedded die 102 can be a radio frequency integrated circuit (RF IC) die, top-side component 116a can be a surface acoustic wave (SAW) die, and top-side component 116b can be a radio frequency (RF) MEMS die.

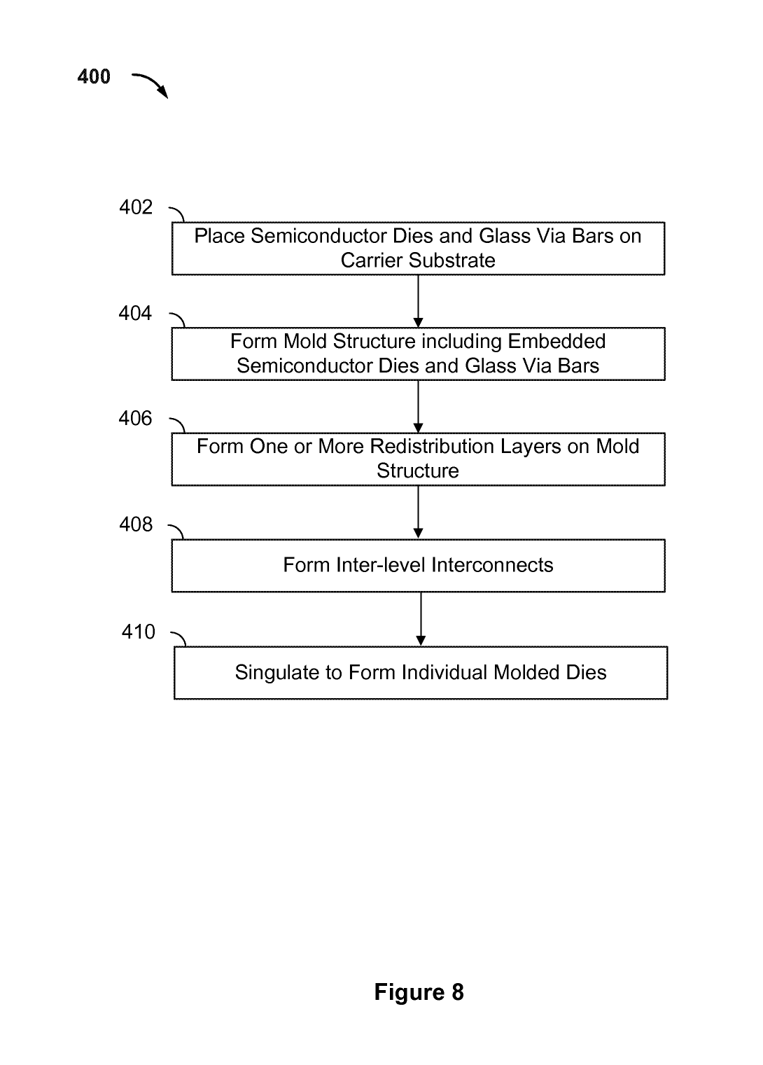

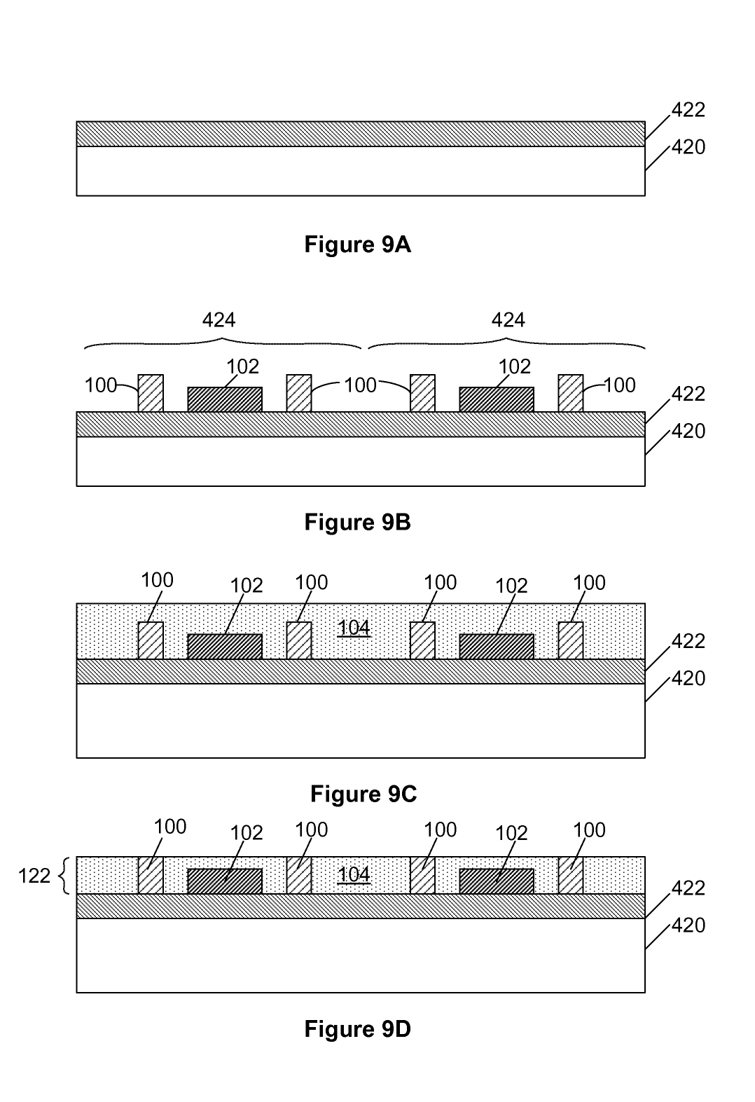

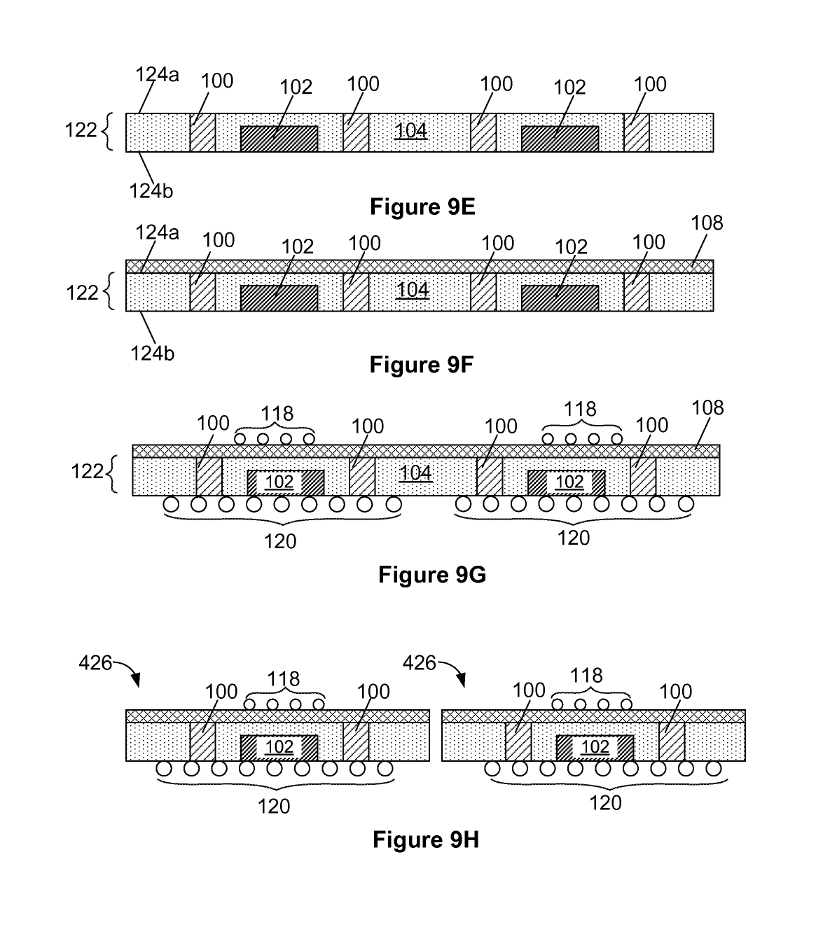

FIG. 8 shows an example of a flow diagram illustrating a packaging process employing a glass via bar. FIGS. 9A-9H show examples of cross-sectional schematic illustrations of various stages in a method of packaging employing a glass via bar. Turning first to FIG. 8, the process 400 begins at block 402 with placing semiconductor dies and glass via bars on a carrier substrate to form a reconfigured wafer. Each semiconductor die and glass via bar will eventually be part of a singulated package containing one or more semiconductor dies and one or more glass via bars. Examples of semiconductor dies can include, but are not limited to, RF IC dies, power management dies, application processors, microcontrollers, and memory dies. The glass via bars can include one or more passive components, such as inductors, capacitors, and resistors, on one or more surfaces. Further, the glass via bars can include one or more through-glass vias connected to form a solenoid-type inductor. In some implementations, passive components can be arranged to form one or more components such as transformers, filters, matching circuits, power combiners, and antennas. In some implementations, the glass via bars are configurable glass via bars.

FIG. 9A shows an example of a cross-sectional schematic illustration of a carrier substrate. A layer of molding tape 422 is disposed on the carrier substrate 420 and provides a surface for the attachment of the semiconductor dies and glass via bars. FIG. 9B shows an example of cross-sectional schematic illustration of semiconductor dies and glass via bars co-located on a carrier substrate. Two packaging units 424 are depicted, each including a semiconductor die 102 and glass via bars 100. The reconfigured wafer may include tens, hundreds or more of such packaging units. Each packaging unit 424 can contain one or more semiconductor dies 102 and one or more glass via bars 100, such that the correspondence between the number of semiconductor dies and glass via bars can be less than, equal to, or greater than one-to-one. In some implementations, the number of glass via bars in a packaging unit 424 is greater than the number of semiconductor dies 102. The semiconductor dies 102 and the glass via bars 100 can be tested prior to being placed on the carrier substrate.

Returning to FIG. 8, the process 400 continues at block 404 with formation of a mold structure including embedded semiconductor dies and glass via bars. Block 404 can include encapsulating the semiconductor dies and glass via bars with a mold compound, such as an epoxy mold compound, and curing the mold compound. Block 404 can further include grinding the mold compound to expose at least the through-glass vias of the glass via bars. In some implementations, the mold structure can then be detached from the carrier substrate for further processing.

FIG. 9C shows an example of a cross-sectional schematic illustration of a glass via bars 100 and semiconductor dies 102 embedded in a mold compound 104. FIG. 9D shows an example of a cross-sectional schematic illustration of a mold structure 122. The mold compound 104 is ground back to expose the through-glass vias (not shown) of the glass via bars 100. The mold structure 122 includes the mold compound 104 as well as the semiconductor dies 102 and the glass via bars 100. FIG. 9E shows an example of a cross-sectional schematic illustration of the mold structure 122 detached from a carrier substrate. The mold structure includes a top surface 124a and a bottom surface 124b available for electrical connection to the semiconductor dies 102 and/or glass via bars 100.

Returning to FIG. 8, the process 400 continues at block 406 with the formation of one or more redistribution layers (RDLs) on the mold structure. Block 406 can include one or more deposition, plating and patterning operations of dielectric and conductive materials to form routing for signals, power and ground, for example. In some implementations, block 406 can include electroplating Cu or other metallization and spin-coating and patterning a dielectric material by photolithography. Examples of dielectric materials include a polyimide material, a benzocyclobutene material, a polybenzoxazole material, and an ABF film available from Ajinomoto Fine-Techno.

If the glass via bars are configurable glass via bars that have not yet been configured, block 406 can include configuration of the configurable glass via bars. For example, routing lines can be plated to configure one or more configurable glass via bars.

FIG. 9F shows an example of a cross-sectional schematic illustration of a package including a mold structure 122 and a RDL 108. The RDL 108 is on the top surface 124a of the mold structure 122 and can include routing and RDL pads (not shown) that provide a contact point for one or more overlying dies or other components. In some implementations, the RDL 108 can include conductive pathways between through-glass vias on the glass via bars 100 to form inductors (not shown). In some implementations, the RDL 108 can include conductive pathways between passive components (not shown) integrated on or in the glass via bars 100 and through-glass vias to connect the semiconductor dies 102 to the passive components. An RDL (not shown) may also be formed on the bottom surface of the mold structure 122 to provide connections between the glass via bars 100 and the semiconductor dies 102.

The process 400 continues at block 406 with the formation of inter-level interconnects. Block 406 can include placement of solder balls on one or both sides of the package. FIG. 9G shows an example of a cross-sectional schematic illustration of a package including solder balls placed on the top and bottom surfaces of a package. Inter-level interconnects 118 and 120 are solder balls in the example of FIG. 9G, with inter-level interconnects 118 having a smaller pitch than the inter-level interconnects 120. The process 400 can continue at block 410 with singulation of the reconfigured wafer to form individual molded dies. Each molded die can include at least one semiconductor die and at least one glass via bar. In some implementations, each molded die includes more than one glass via bar for each semiconductor die. FIG. 9H shows an example of a cross-sectional schematic illustration of singulated individual molded dies. Each molded die 426 includes a semiconductor die 103 and glass via bars 100 in electrical communication with inter-level interconnects 118 and 120.

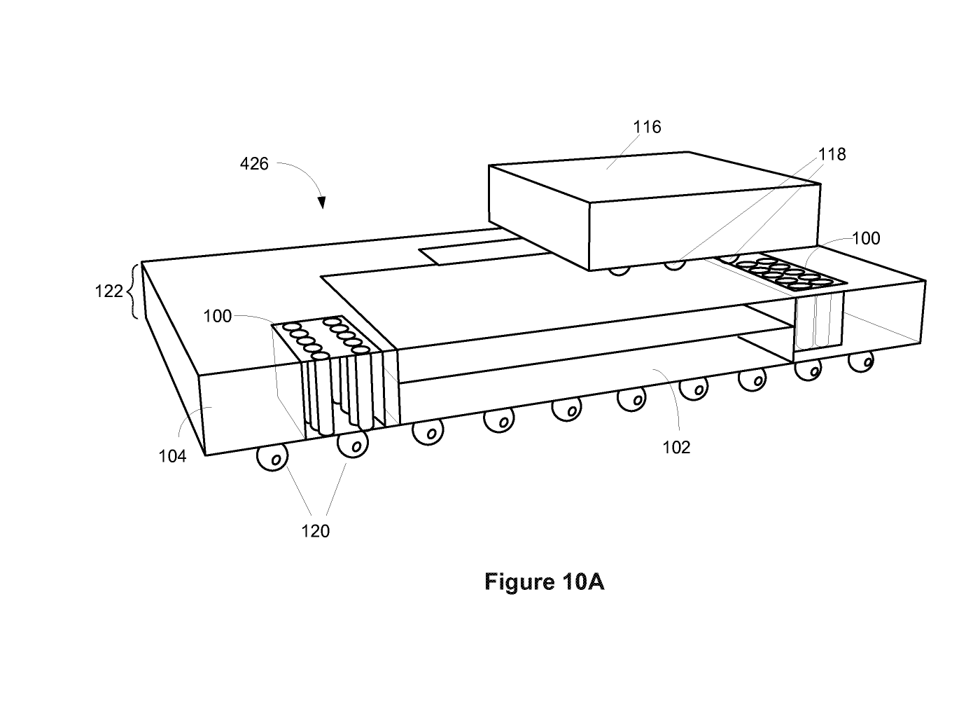

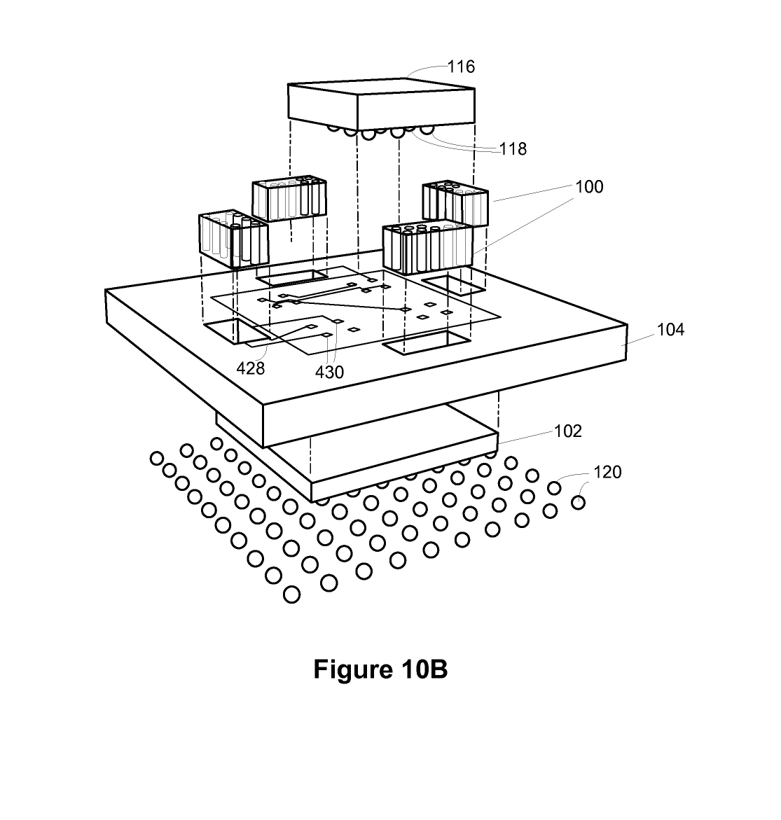

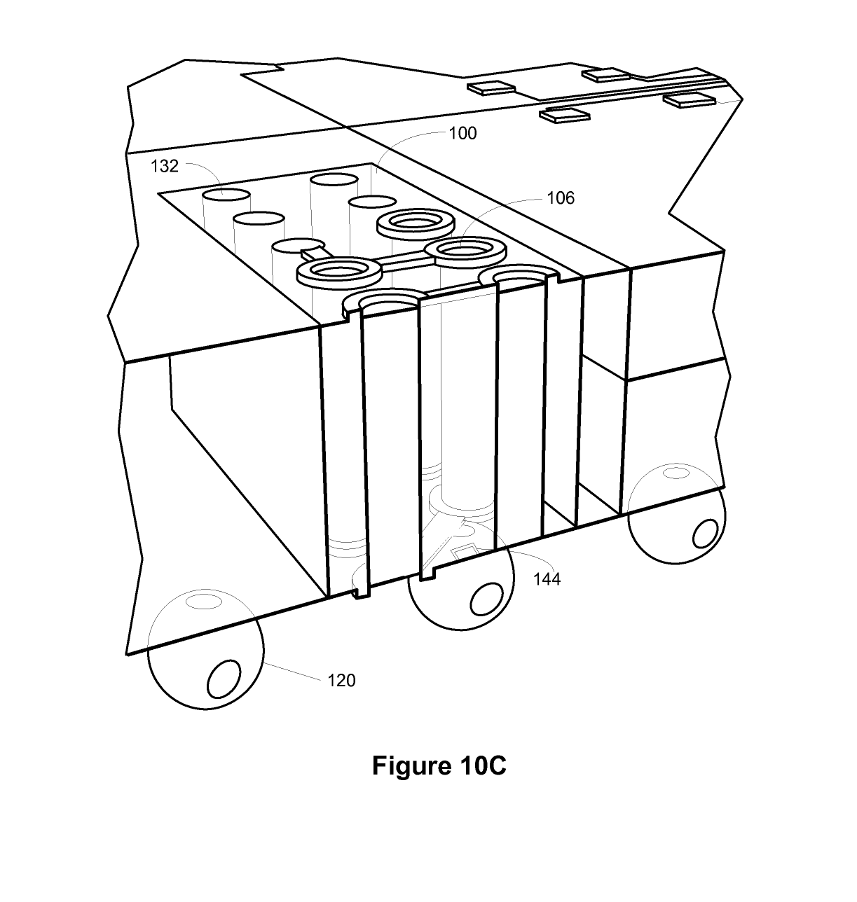

FIGS. 10A-10C show examples of various views of a molded die including an embedded semiconductor die and glass via bars. FIGS. 18A and 18B show examples of cutaway isometric and exploded views, respectively, of a molded die 426. The molded die 426 includes a mold structure 122 and inter-level interconnects 118 and 120. The mold structure 122 includes a semiconductor die 102 and glass via bars 100 embedded in a mold compound 104. The glass via bars 100 are spaced around the perimeter of the semiconductor die 102. In some implementations, the location of a glass via bar 100 and its through-glass vias 106 can be optimized to enable a short electrical path from a section of the semiconductor die 102 to the glass via bar 100 and its through-glass vias 106 and/or passive component, if any. Conductive routing 428 and pads 430 on the top surface of the semiconductor die 103 and the mold compound 104 (FIG. 10B) provide electrical connection between through-glass vias and passive components of the glass via bars 100 and the inter-level interconnects 118. The inter-level interconnects 118 electrically connect top-side component 116. The semiconductor die 102 can be, for example, a RF IC or power management die, with the top-side component a WLCSP die or SMT component. FIG. 10C shows an example of a close-up view of one of the glass via bars 100 embedded in the mold compound 104. A capacitor 144 is formed on the bottom surface of the glass via bar 100. The glass via bar 100 also includes through-glass vias 106, which can be interconnected to form a solenoid-type inductor, and unfilled through-glass via holes 132.

Examples of passives on glass via bars and semiconductor dies that can be packaged together as described above with respect to FIGS. 1A-10C can include capacitors co-packaged with a power management die, high density 3-D capacitors co-packaged with a power management die, and matching circuits network passives co-packaged with an RF IC die. Examples of top- or bottom-side components (such as top-side component 116 in FIGS. 10A and 10B) for a package including matching circuits passives in a glass via bar and a RF IC include SAW filters, tunable components, SMT components, WLCSP MEMS, WLCSP filters, WLCSP dies, and WLCSP additional passives.

In some implementations, the glass via bars described herein can be included in a package-on-package (PoP). PoP methods involve packaging multiple dies in separate packages and then packaging the separate packages together by stacking package on package. In some implementations, each packaged die can be tested prior to stacking to find known good dies. According to various implementations, the PoP's described herein can include multiple discrete packages of any type, including one or more logic, memory or EMS packages. One or more packages in the PoPs described herein can include one or more glass via bars.

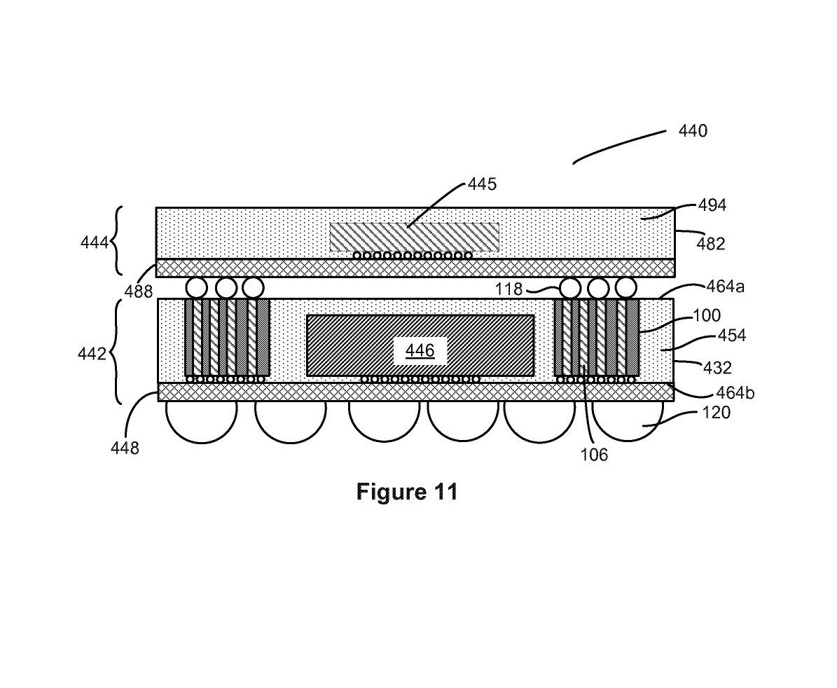

FIG. 11 shows an example of a schematic cross-sectional illustration of a PoP that includes glass via bars. The PoP 440 includes a logic package 442 vertically integrated with a memory package 444. The PoP 440 can be mounted on a electronic device printed circuit board (PCB), such as a mobile phone PCB, via inter-level interconnects 120.

The logic package 442 includes a mold structure 432 and a logic package substrate 448. The mold structure 432 has a top surface 464a and a bottom surface 464b and includes a mold compound 454 as well as components embedded within the mold compound 454; in the example of FIG. 11, these components include a logic die 446 and glass via bars 100. Each of the glass via bars 100 includes through-glass vias 106 that extend through the thickness of the glass via bar 100 and provide electrical connections from the top surface 464a of the mold structure 432 to the bottom surface 464b. While the mold structure 432 in the example of FIG. 11 includes a single die, an arbitrary number of dies can be included according to various implementations. The logic package substrate 448 can be an organic substrate, such as a PCB or polymeric substrate, that can include conductive pathways (not shown) and contact pads (not shown). The through-glass vias 106 can be electrically connected to the logic die 446 by electrical routing on the bottom surface 464b of mold structure 432 and/or electrical routing in or on the logic package substrate 448. Conductive pathways and contacts pads in or on logic package substrate 448 can provide an electrical connection from the logic package 442 to the inter-level interconnects 120. The through-glass vias 106 can provide an electrical connection to the inter-level interconnects 118, which connect the logic package 442 to the memory package 444. In some implementations, a RDL (not shown) may be included on the top surface 464a of the mold structure to provide an electrical connection to the inter-level interconnects 118. In the example of FIG. 11, the logic die 446 and the through-glass vias 106 are electrically connected to the logic package substrate 448 by flip-chip attachment, which in turn provides an electrical connection to inter-level interconnects 120.

The memory package 444 includes a mold structure 482 and a memory package substrate 488. The mold structure 482 includes a mold compound 494 and components embedded within the mold compound 494; in the example of FIG. 11, these components include a memory die stack 445. The memory die stack 445 includes one or more memory dies. In the example of FIG. 11, the memory die stack 445 is electrically connected to the memory package substrate 488 by flip-chip attachment, which in turn provides an electrical connection to inter-level interconnects 118. In some other implementations, one or more memory dies are wire bonded or otherwise connected to the memory package substrate 448.

It should be noted that the size, pitch, and placement of the inter-level interconnects 118 and the inter-level interconnects 120, as well as of the flip-chip attachments of the memory die stack 445, the logic die 446, and the through-glass via bars 100 can be varied as appropriate. For example, the size and/or pitch of solder balls that connect the through-glass vias 106 to the logic package substrate 448 may be the same as the inter-level interconnects 118.

In some implementations, the glass via bars 100 can include one or more integrated capacitors (not shown) as described above with reference to FIGS. 4-5G. Because the capacitors are integrated with the glass via bars 100, the glass via bars 100 and the capacitors can be placed closer to the logic die 446 than if the capacitors were discrete components, reducing path length and increasing efficiency. In addition to reducing the path length, the glass via bars 100 can reduce the footprint of the logic package 442 and the footprint of the PoP 440. In some implementations, the footprint of the memory package 444 can be reduced by including a memory die stack 444 attached to the memory package substrate 488 by flip-chip attachment as in the example of FIG. 11 rather than by wire bonds.

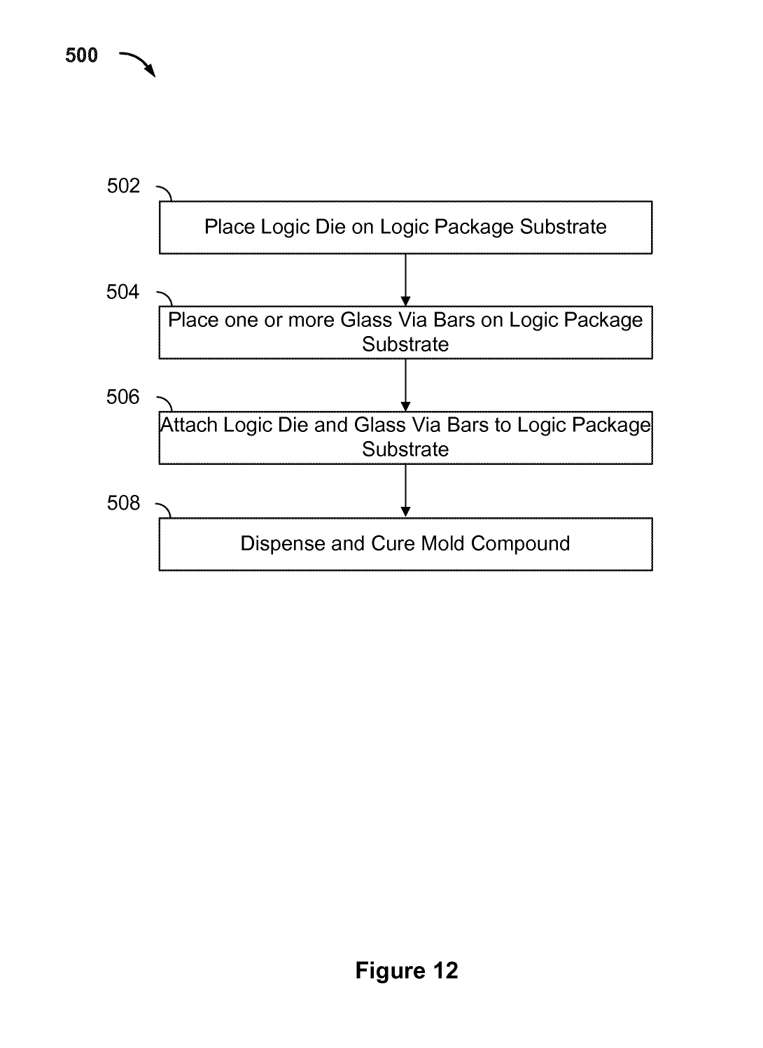

FIG. 12 shows an example of a flow diagram illustrating a PoP packaging process employing a glass via bar. In the example of FIG. 12, a process 500 for manufacturing a logic package for a PoP is described. The process 500 begins at block 502 with placing a logic die on a logic package substrate. Examples of logic dies include but are not limited to application processors. In some implementations, the logic die is tested prior to block 502. This allows only a known good die to be incorporated into the logic package and the PoP. The process 500 continues at block 504 with placing one or more glass via bars on the logic package substrate. The glass via bars can include one or more capacitors or other passive components on one or more surfaces. In some implementations, the glass via bars are tested prior to block 504. This allows only known good via bars to be incorporated in the logic package and the PoP. Once the logic die and the one or more glass via bars are placed, they are attached to the logic package substrate. The logic die and the one or more glass via bars can be attached simultaneously to the logic package substrate. The process 500 continues at block 508 with dispensing and curing a mold compound. Additional operations such as solder ball mount can then be performed and package testing. Once formed, the logic package can be stacked with one or more additional packaged dies to form a PoP.

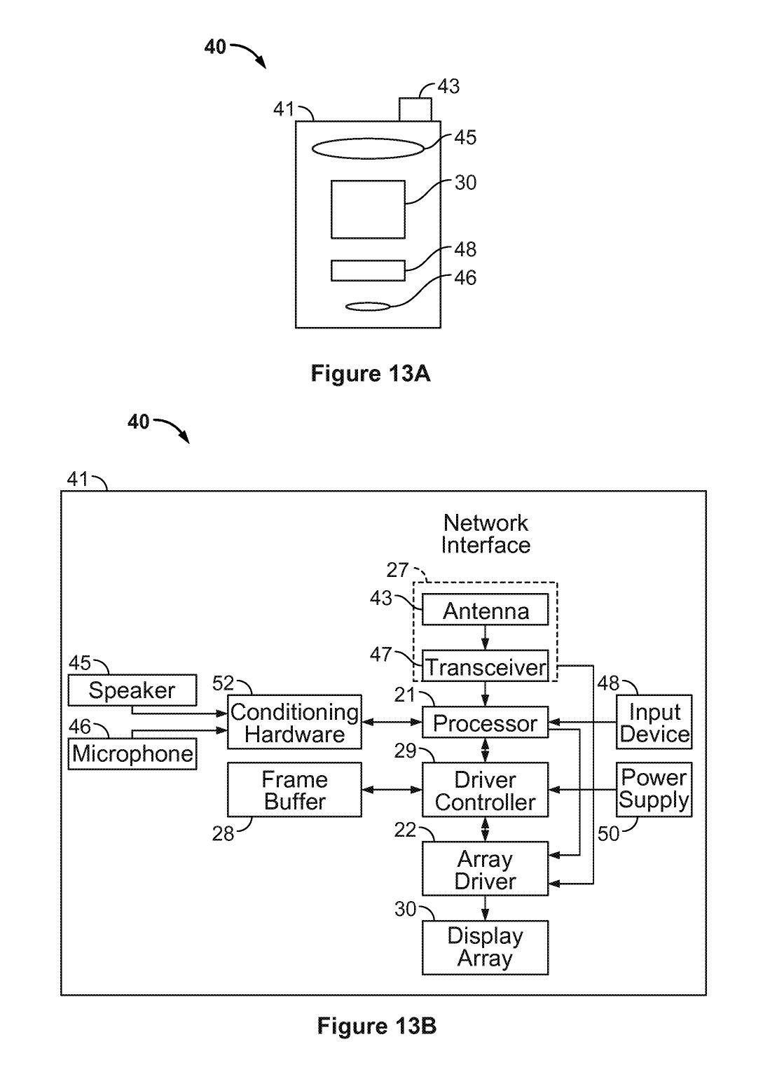

In some implementations, the glass via bar can be included as part of a display device, or in a package including a display device. FIGS. 13A and 13B show examples of system block diagrams illustrating a display device 40. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11 a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

In various implementations of the display device 40, one or more of the antenna 43, transceiver 47, processor 21, driver controller 29, frame buffer 28, speaker 45, microphone 46, array driver 22, power supply 50, and input device 48 can include a package with a semiconductor die embedded in a molded die with a glass via bar or a package in which a semiconductor die and a glass via bar are both bonded to the same substrate. For example, the processor 29 may include an eWLP or PoP package that includes a semiconductor processor die and a glass via bar. As another example, power supply 50 can include a glass via bar configured as a solenoid-type inductor.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus. If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a glass bar including one or more through-glass vias, wherein the thickness of the glass bar is between about 300 and 700 microns and the length and width of the glass bar are each between about 1 and 15 millimeters.

2. The apparatus of claim 1, wherein glass bar includes photo-patternable glass.

3. The apparatus of claim 1, wherein the through-glass vias have a density of 6 vias per millimeter square to 200 vias per millimeter square.

4. The apparatus of claim 1, wherein the glass bar includes one or more passive devices.

5. The apparatus of claim 4, wherein the one or more passive devices include one or more of an inductor, a capacitor and a resistor.

6. The apparatus of claim 4, wherein at least one of the one or more passive devices is connected to at least one of the one or more through-glass vias.

7. The apparatus of claim 4, wherein the one or more passive devices can be configured during an embedded wafer-level process.

8. The apparatus of claim 1, wherein the glass bar includes configurable passive devices.

9. The apparatus of claim 1, wherein the glass bar includes two or more through-glass vias connected to form an inductor.

10. The apparatus of claim 1, wherein the through-glass vias have a diameter between about 30 microns and 50 microns.

11. The apparatus of claim 1, wherein the through-glass vias include plated copper.

12. A package comprising:
a glass bar including one or more through-glass vias; and
a mold embedding the glass bar.

13. The package of claim 12, wherein the package further includes a semiconductor die embedded in the mold and in electrical communication with the one or more through-glass vias.

14. The package of claim 12, wherein the package includes a single semiconductor die and a plurality of glass bars embedded in the mold.

15. The package of claim 12, wherein a plurality of semiconductor dies and associated glass via bars are embedded in the mold.

16. The package of claim 12, wherein the glass bar includes one or more passive devices.

17. The package of claim 16, wherein the one or more passive devices are selected from an inductor, a capacitor and a resistor.

18. The package of claim 12, wherein the glass bar includes a photo-patternable glass.

19. A system comprising the package of claim 12, the system further comprising:
a display;
a processor that is configured to communicate with the display, the processor being configured to process image data; and
a memory device that is configured to communicate with the processor.

20. The system of claim 19, further comprising:
a driver circuit configured to send at least one signal to the display; and
a controller configured to send at least a portion of the image data to the driver circuit, wherein one or more of the processor, memory device, driver circuit, and controller include components embedded in the mold.

21. The system of claim 19, further comprising:
an image source module configured to send the image data to the processor,
wherein the image source module includes at least one of a receiver, transceiver, and transmitter and wherein one or more of the processor, memory device, receiver, transceiver, and transmitter include components embedded in the mold.

22. The system of claim 19, further comprising:
an input device configured to receive input data and to communicate the input data to the processor.

23. A method comprising:
forming a plurality of passive components on a glass substrate;
forming a plurality of through-glass via holes in the glass substrate;
metallizing the through-glass via holes; and
singulating the glass substrate to form a plurality of glass via bars each having a thickness of the glass bar between about 300 and 700 microns and a length between between about 1 and 15 millimeters.

24. The method of claim 23, wherein the glass substrate is a photo-patternable glass substrate and forming the plurality of through-glass via holes includes patterning and etching the photo-patternable glass substrate.

25. The method of claim 23, wherein forming the plurality of through-glass via holes includes laser ablation of the glass substrate.

26. The method of claim 23, wherein metallizing the through-glass via holes includes electroplating.

27. The method of claim 23, further comprising connecting one or more of the plurality of passive devices to at least one of the plurality of metallized through-glass via holes.

28. The method of claim 23, further comprising connecting two or more of the plurality of metallized through-glass via holes to form an inductor.

29. A method comprising:
placing a plurality of semiconductor dies and a plurality of glass via bars on a carrier substrate;
embedding the plurality of semiconductor dies and the plurality of glass via bars in a mold compound to form a mold structure;
forming one or more redistribution layers on the mold structure;
forming inter-level interconnects; and
singulating the mold structure to form a plurality of molded dies each including at least one semiconductor, at least one glass via bar, and a plurality of inter-level interconnects.

30. The method of claim 29, wherein the plurality of glass via bars includes integrated passive components.
